(19) United States
(12) Patent Application Publication
(10) Pub. No.: US 2022/0052237 A1
(43) Pub. Date: Feb. 17, 2022

(54) SURFACE SHIELDING ASSEMBLY FOR LED PACKAGE

(71) Applicant: SHENZHEN REFOND OPTOELECTRONICS CO., LTD., Guangdong (CN)

(72) Inventors: ZHI YOU, GUANGDONG (CN); XIAOMING PEI, GUANGDONG (CN)

(21) Appl. No.: 17/414,113

(22) PCT Filed: Nov. 8, 2019
(86) PCT No.: PCT/CN2019/116468

§ 371 Date: Jun. 15, 2021

(30) Foreign Application Priority Data
Dec. 17, 2018 (CN) 201822114133.8

(51) Int. Cl. H01L 33/60; H01L 33/54

(52) U.S. Cl. CPC H01L 33/60; H01L 33/56; H01L 33/54

(57) ABSTRACT

A surface shielding assembly for LED packaging, including: an LED luminescent module (1), a sealing member (2), and a reflective layer (3). The LED luminescent module (1) is encapsulated within the sealing member (2). The sealing member (2) has a plurality of light emergent surfaces. A reflective layer (3) is at least arranged on a light emergent surface facing the LED luminescent module (1). The reflective layer (3) is capable of partially or totally reflecting light rays emitting from the LED luminescent module (1) to other light emergent surfaces. By arranging the reflective layer (3) in a direction facing the LED luminescent module (1), the light emitted from the LED luminescent module is emergent from other light emergent surfaces at lateral sides, in this way, the light intensity and the overall light-emitting angle of the lateral sides of the LED lamp are increased, thereby changing the over-bright light spot caused by the excessive light intensity at the front side in the prior art, reducing the intensity of the central light, and achieving the effect of improving the uniformity of the light spot.

### TECHNICAL FILED

The present application relates to the technical field of LED packaging, and more particularly to a surface shielding assembly for LED packaging.

### BACKGROUND

Light emitting diode (LED) has been extensively applied in various technical field, currently, due to their low power consumption, long service life, and small volume. According to different use environment and purposes, LED lamps with different structures can be devised.

It can be found from different structures and installation manners of the LED chips that the light emitted from the LED is directional, which cannot be emitted at an angle of greater than 180° or even approximately 360° in some cases, as the traditional light source. Therefore, when devising the LED lamp, the light emergent surface of the LED light source is arranged according to use requirement such that the light emitted therefrom is in the expected light emitting direction of the lamp, thereby satisfying the irradiation condition. A typical LED package adopt a front side-light emitting structure, and the emitted light presents a Lambertian light shape, which features high light intensity in a center and low light intensity at a periphery, thereby resulting in a bright spot. Such condition may cause un-uniform light emission of the LED lamp, and the light will be dazzling, causing the color difference between the LED point light sources and affecting the overall light perception of the LED lamp.

In the prior art, especially in areas that require high light uniformity, such as TV backlights and of panel lamps adopting surface light sources, it is necessary to add a secondary optical lens to increase the light angle of the light source, thereby increasing the uniformity of the light spot. However, adding an optical lens will result in an increase in cost and size.

In view of this, it is an objective of the present application to provide a new technical solution to solve the existing technical defects.

### SUMMARY

It is an objective of the present application to provide a surface shielding assembly for LED packaging. By arranging a shielding assembly in the LED packaging device, a reflective layer is at least arranged at a light emergent surface facing the LED luminescent module, such that the light rays emitted from the front side of the LED is reflected and therefore a part of or all of the light rays are emergent from lateral sides or other light emergent surfaces.

In view of the above technical problems, technical solutions adopted by the present application are as follows:

A surface shielding assembly for LED packaging, comprises: an LED luminescent module, a sealing member, and a reflective layer. The LED luminescent module is encapsulated within the sealing member. The sealing member has a plurality of light emergent surfaces. A reflective layer is at least arranged on a light emergent surface facing the LED luminescent module. The reflective layer is capable of partially or totally reflecting light rays emitting from the LED luminescent module to other light emergent surfaces.

In a preferred embodiment of the present application, the reflective layer is made of an opaque material or a semi-transparent material.

In a preferred embodiment of the present application, a reflective surface of the reflective layer is a flat surface, an inclined surface, an arc surface, or a wavy surface.

In a preferred embodiment of the present application, the sealing member is integrally formed by a packaging colloid.

In a preferred embodiment of the present application, the packaging colloid is a silica gel or an epoxy resin.

In a preferred embodiment of the present application, the sealing member and the reflective layer are bonded by fusion.

In a preferred embodiment of the present application, the sealing member and the reflective layer are bonded by gluing.

Advantages of the surface shielding assembly for LED packaging according to embodiments of the present application are summarized as follows:

The reflective layer made of the white opaque material or the semi-transparent material is adopted, the reflective layer is arranged to face the LED luminescent module, such that the light emitted from the LED luminescent module is emergent from other light emergent surfaces at lateral sides, in this way, the light intensity and the overall light-emitting angle of the lateral sides of the LED lamp are increased, thereby changing the over-bright light spot caused by the excessive light intensity at the front side in the prior art, reducing the intensity of the central light, and achieving the effect of improving the uniformity of the light spot.

### BRIEF DESCRIPTION OF THE DRAWINGS

The present application is further illustrated with reference to accompanying drawings and embodiments.

FIG. 1 is a front view of an embodiment of the present application;

FIG. 2 is a left view of an embodiment of the present application;

FIG. 3 is a second front view of an embodiment of the present application;

and

FIG. 4 is a third front view of an embodiment of the present application;

### DETAILED DESCRIPTION OF THE EMBODIMENTS

Concepts, specific structures, and technical effects of the present application will be clearly and completely described hereinbelow with reference to the embodiments and the drawings, so as to fully understand the objectives, solutions, and effects of the present application. It should be noted that the embodiments of the present application and the features in the embodiments can be combined with one another, as long as no conflict occurs.

It should be noted that, unless otherwise specified, when a feature is called “fixed” or “connected” to another feature, it can be directly fixed and connected to another feature, or indirectly fixed or connected to another feature. In addition, top, bottom, left, right and other descriptions used in the present application are only relative to the mutual positional relationship of the components of the present application in the drawings.

In addition, unless otherwise defined, all technical and scientific terms used herein have the same meaning as commonly understood by those skilled in the art. The terminology used in the specification herein is only for describing specific embodiments, but is not intended to limit the present application. The term “and/or” as used herein includes any combination of one or more related items listed.

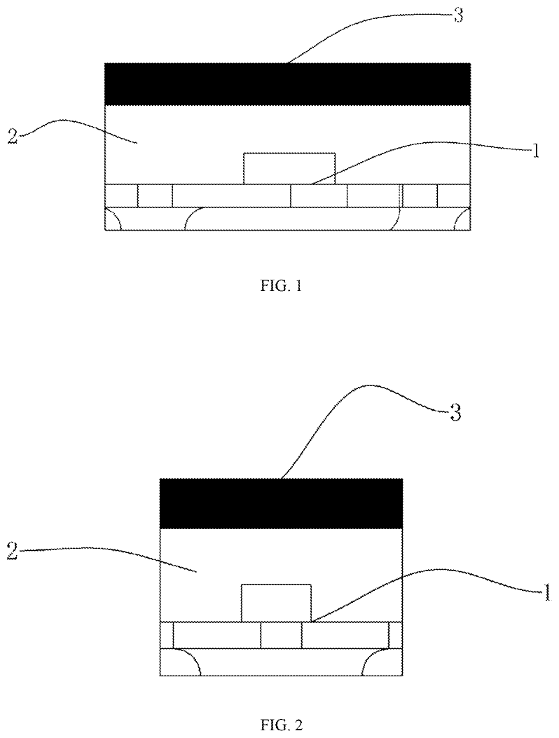

FIGS. 1-2 are front view and left view of an embodiment of the present application, as shown in FIGS. 1-2, a surface shielding assembly for LED packaging, comprises: an LED luminescent module 1, a sealing member 2, and a reflective layer 3. The LED luminescent module 1 is arranged at a bottom of an LED device and in electric connection with an external circuit. The well assembled LED luminescent module 1 is encapsulated within the sealing member 2. The reflective layer 3 is fixed outside the sealing member 2. The LED luminescent module 1 comprises a substrate and an LED chip fixed at the substrate. When powered on, the LED luminescent module 1 emits light from a front side of the LED chip to the outside. The LED chip is fixed to the substrate by a thermally conductive adhesive, that is, a die bonding process is completed in a designated area of the substrate. The substrate can be a metal substrate with a high thermal conductivity (such as an aluminum or copper substrate), a silicon substrate, or a ceramic substrate. In the meanwhile, the LED chip can be a blue light chip or an ultraviolet light chip of the same waveband or different wavebands according to needs. In other embodiments, the LED luminescent module 1 can also have a variety of combinations and modifications, which are conventional technical means in the field and will not be repeated herein.

As shown in FIGS. 1-2, a packaging colloid is applied outside the LED luminescent module 1 in order to package the LED luminescent module 1, whereby forming the sealing member 2. The packaging process may adopt an integral formation by integrally applying an adhesive, or alternatively, arranging a transparent casing outside the LED luminescent module 1 and using the packaging colloid for packaging, whereby forming the sealing member 2 and completing the sealing of the LED device. The packaging colloid is made of a thermosetting material, and the thermosetting material is a silica gel or an epoxy resin. In the meanwhile, the packaging colloid may be mixed with a corresponding phosphor according to practical needs, so as to excite light of different wavelengths.

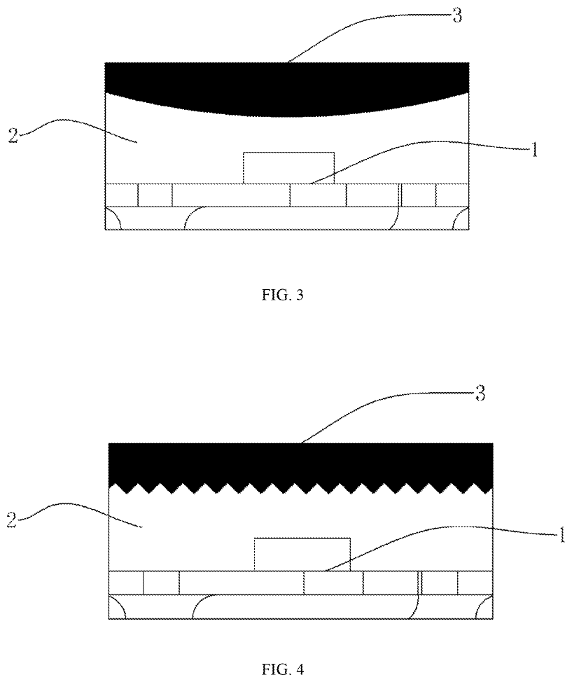

After completing the packaging, in this embodiment, a plurality of light emergent surfaces are formed on the transparent sealing member 2. A reflective layer 3 is at least arranged at a light emergent surface facing the LED luminescent module 1 and above the sealing member. In other embodiments, the plurality of light emergent surfaces may also be formed on the reflective layer 3, according to the use requirement, so as to control the light emitting direction of the LED device. As shown in FIGS. 1-4, one side of the reflective layer 3 facing the LED luminescent module 1 is a reflective surface, and the reflective surface of the reflective layer is a flat surface, an inclined surface, an arc surface, or a wavy surface, and a proper reflective surface can be selected according to practical needs. The reflective layer 3 may be a white opaque material or other semi-transparent materials, and the thickness or light transmittance of the reflective layer 3 can be adjusted according to the use requirements, so as to adjust the intensity of the light passing through the reflective layer 3. In this embodiment, the reflective layer 3 can be made of an organic polymer material, such as polyvinyl chloride (PVC), polycarbonate (PC), polyethylene (PE), etc., or can be made of other opaque or translucent materials. The above-mentioned material can be heated to be fused so as to be fused together with the sealing member 2, or alternatively a thermosetting adhesive or other adhesives can be used for gluing the reflective layer 3 together with the sealing member 2. In this embodiment, the reflective layer 3 is coated on the packaging surface as a whole before being separated in the packaging process, and then individual devices are separated, thereby improving production efficiency.

When in use, the LED luminescent module 1 emits light after being powered on, and the light is emitted from the front side of the LED chip. In this embodiment, the reflective layer 3 is arranged at the light emergent surface facing the light emitting direction. When the light is irradiated onto the reflective surface of the reflective layer 3, a part of or all of the light is reflected once or many times by the reflective surface, and then emergent from other light emergent surfaces where no reflective layer 3 is arranged. In this way, it is realized that on the premise of no additional optical lens, the luminous intensity of the front side of the LED device is adjusted, at the same time the luminous intensity of the lateral sides of the LED device and the overall luminous angle are increased, thereby improving the uniformity of the light spot at the receiving end.

The above is only a detailed description of the preferred embodiments of the present application, but the present application is not limited to the described embodiments. Various equivalent modifications or substitutions can be made by those skilled in the art without departing from the spirit of the present application, and such equivalent modifications or replacements are all included in the scope defined by the claims of the present application.

A surface shielding assembly for LED packaging, including: an LED luminescent module (1), a sealing member (2), and a reflective layer (3). The LED luminescent module (1) is encapsulated within the sealing member (2). The sealing member (2) has a plurality of light emergent surfaces. A reflective layer (3) is at least arranged on a light emergent surface facing the LED luminescent module (1). The reflective layer (3) is capable of partially or totally reflecting light rays emitting from the LED luminescent module (1) to other light emergent surfaces. By arranging the reflective layer (3) in a direction facing the LED luminescent module (1), the light emitted from the LED luminescent module is emergent from other light emergent surfaces at lateral sides, in this way, the light intensity and the overall light-emitting angle of the lateral sides of the LED lamp are increased, thereby changing the over-bright light spot caused by the excessive light intensity at the front side in the prior art, reducing the intensity of the central light, and achieving the effect of improving the uniformity of the light spot.

1. A surface shielding assembly for LED packaging, comprising:
an LED luminescent module,
a sealing member, and
a reflective layer;
wherein
the LED luminescent module is encapsulated within the sealing member;
the sealing member has a plurality of light emergent surfaces at least one of which faces the LED luminescent module;
a reflective layer is at least arranged on the at least one light emergent surface facing the LED luminescent module; and
the reflective layer operates to partially or totally reflect light rays emitting from the LED luminescent module to other ones of the plurality of light emergent surfaces.

2. The surface shielding assembly for LED packaging according to claim 1, wherein the reflective layer is made of an opaque material or a semi-transparent material.

3. The surface shielding assembly for LED packaging according to claim 1, wherein a reflective surface of the reflective layer comprises a flat surface, an inclined surface, an arc surface, or a wavy surface.

4. The surface shielding assembly for LED packaging according to claim 1, wherein the sealing member is integrally formed by a packaging colloid.

5. The surface shielding assembly for LED packaging according to claim 4, wherein the packaging colloid is a silica gel or an epoxy resin.

6. The surface shielding assembly for LED packaging according to claim 1, wherein the sealing member and the reflective layer are bonded by fusion.

7. The surface shielding assembly for LED packaging according to claim 1, wherein the sealing member and the reflective layer are bonded by adhesion.
